(19) United States
(12) Patent Application Publication
(10) Pub. No.: US 2013/0026340 A1
(43) Pub. Date: Jan. 31, 2013

(54) ELECTRONIC DEVICE EMPLOYING A BUTTON PAD

(71) Applicants: Yoshiaki KANAMORI, Hyogo (JP); Masayoshi MUKAIDE, Kyoto (JP)

(72) Inventors: Yoshiaki KANAMORI, Hyogo (JP); Masayoshi MUKAIDE, Kyoto (JP)

(73) Assignee: SANYO ELECTRIC CO., LTD., Moriguchi City (JP)

(21) Appl. No.: 13/558,975

(22) Filed: Jul. 26, 2012

(30) Foreign Application Priority Data
Jul. 28, 2011 (JP) 2011-165100
Jul. 28, 2011 (JP) 2011-165102
Jul. 28, 2011 (JP) 2011-165104

(51) Int. Cl. H05K 5/06; G01J 1/04; H01H 13/06

(52) U.S. Cl. 250/200; 200/302.2; 361/724

(57) ABSTRACT

A display device has a cabinet; a button provided on the cabinet; a switch being pushed by the button; a circuit board including the switch, and a button pad which comprises: (a) a button portion; (b) a peripheral portion which is in the surroundings of the button portion, and (c) a plurality of annular ribs provided on the button pad in a position corresponding to the periphery of the button, wherein, each of the rib is arranged so as to contact the inner surface of the cabinet.

### CROSS-REFERENCE TO RELATED APPLICATIONS

This application claims the benefit of priority of Japanese Patent Application No. 2011-165100, 2011-165102, and 2011-165104, all of which are filed on Jul. 28, 2011, and all of which are incorporated by reference herein in their entirely.

### TECHNICAL FIELD

The instant application relates to a water-proofing structure of an electronic device for outdoor use such as display device.

### BACKGROUND

In recent years, digital signage monitors for outdoor use is increasing. In these monitors, the measures against heat and water are taken so that these monitors can be installed outdoors.

In these monitors is desired to arrange an operation button on the cabinet so that a user can make operate such as tuning a channel or volumes like they do in indoor use monitors. However, in the outdoor monitors, water may intrude inside the cabinet from the button portion.

### SUMMARY

In one general aspect, the instant application describes a button pad made by an elastic component, having a protruding portion provided in a position corresponding to one or more buttons and a plurality of annular ribs provided in the periphery of the single button.

In one general aspect, the instant application describes an electronic device, having a cabinet; a button provided on the cabinet; a switch being pushed by the button; a circuit board including the switch. The button pad which includes, (a) a button portion; (b) a peripheral portion which is in the surroundings of the button portion, and (c) a plurality of annular ribs provided on the button pad in a position corresponding to the periphery of the button, wherein, each of the rib is arranged so as to contact the inner surface of the cabinet.

### BRIEF DESCRIPTION OF THE DRAWINGS

The figures depict one or more implementations in accord with the present teachings, by way of example only, not by way of limitations. In the figures, like reference numerals refer to the same or similar elements.

FIG. 1 is an exploded view of the liquid crystal display 10.

FIG. 2 is a front perspective view of the button pad 30.

FIG. 3 is another front perspective view of the button pad 30.

FIG. 4 is a front view of the button pad 30.

FIG. 5 is a back perspective view of the button pad 30.

FIG. 6 is a side perspective view of the button pad 30.

FIG. 7 is a rear view of the button pad 30.

FIG. 8 is a left side view of the button pad 30.

FIG. 9 is a sectional view along the line 8-8 of FIG. 6.

FIG. 10 is a sectional view along the line 8-8 of FIG. 6.

FIG. 11 is another sectional view of the button pad 30.

FIG. 12 is a front view of the button pad 30 when it is equipped to the cabinet 20.

FIG. 13 is a sectional view of the button pad 30 when it is equipped to the cabinet 20.

FIG. 14 is a perspective view of a waterproofing structure of the accommodation unit 100 accommodating a plug for cable and a cover 140.

FIG. 15 is a sectional view of the accommodation unit 100.

FIG. 16 is a front view of the display device 10.

FIG. 17 is a sectional view of the device unit 90 portion in the horizontal direction.

FIG. 18 is a sectional view of the device unit 90 portion in the vertical direction.

FIG. 19 is an exploded view of the device unit 90.

FIG. 20 is a sectional view of the handle 80 portion.

FIG. 21 is an exploded view of the handle 80 portion.

### DETAILED DESCRIPTION

In the following detailed description, numerous specific details are set forth by way of examples in order to provide a thorough understanding of the relevant teachings. However, it should be apparent to those skilled in the art that the present teachings may be practiced without exemplary details. In other instances, well known methods, procedures, components, and/or circuitry have been described at a relatively high-level, without detail, in order to avoid unnecessarily obscuring aspects of the present concepts. In exchange for the present disclosure herein, the Applicants desire all patent rights described in the claims. Therefore, the patent rights are not intended to be limited or restricted by the following detailed description and accompanying figures.

### 1) Waterproofing Structure of a Button Portion

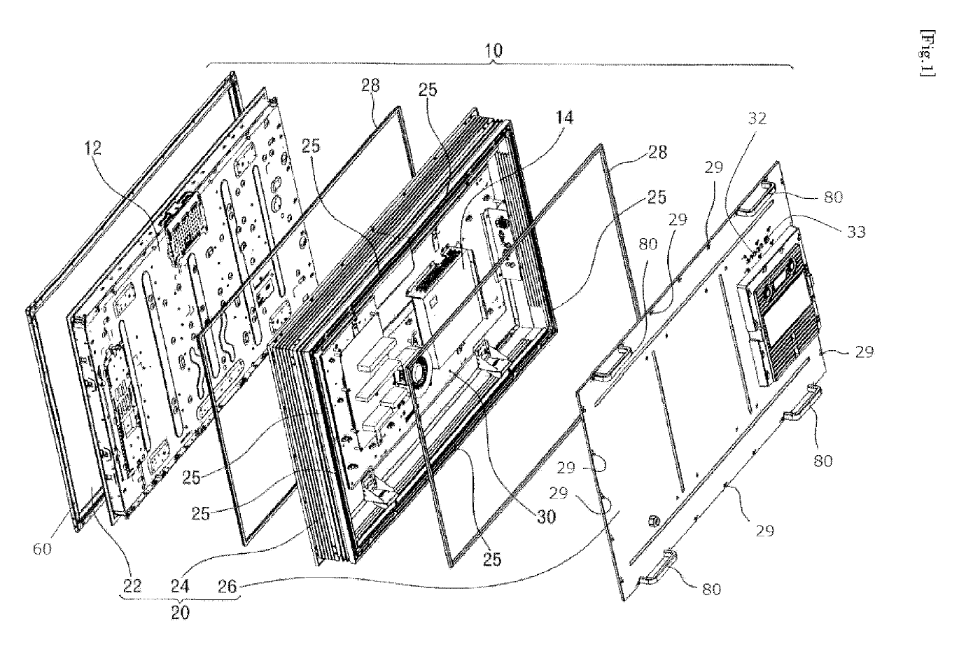

FIG. 1 is an exploded perspective view of a liquid crystal display 10 (LCD display 10). LCD display 10 has a liquid crystal panel unit 12 (LCD panel unit 12) and an electronic-circuit unit 14. The LCD panel unit 12 has a LCD panel in its front side. The electronic-circuit unit 14 performs various control of the LCD panel unit 12. The cabinet 20 accommodates the LCD panel unit 12 and the circuit unit 14.

The cabinet 20 comprises a glass panel 22, side casing 24 and rear panel 26. The glass panel 22 covers the front side of the LCD panel unit 12. The side casing 24 is rectangular shaped and covers the side surface of the LCD panel unit 12 and the electronic-circuit unit 14. The rear panel 26 covers the side casing 24 from the back side. The glass panel 22 and the side casing 24 are connected with a gasket 28 in between. Simultaneously, the side casing 24 and the rear panel 26 are connected with a gasket 28 in between. Thereby, the inside of the cabinet 20 is waterproofed. In this LCD display device 10, the side casing 24 and the rear panel 26 are made by aluminum alloy. An operation unit, which is configured by push buttons 32 and 33, is provided in the right upper side of the rear panel 26 above the accommodation unit 100 which is covered by cover 140.

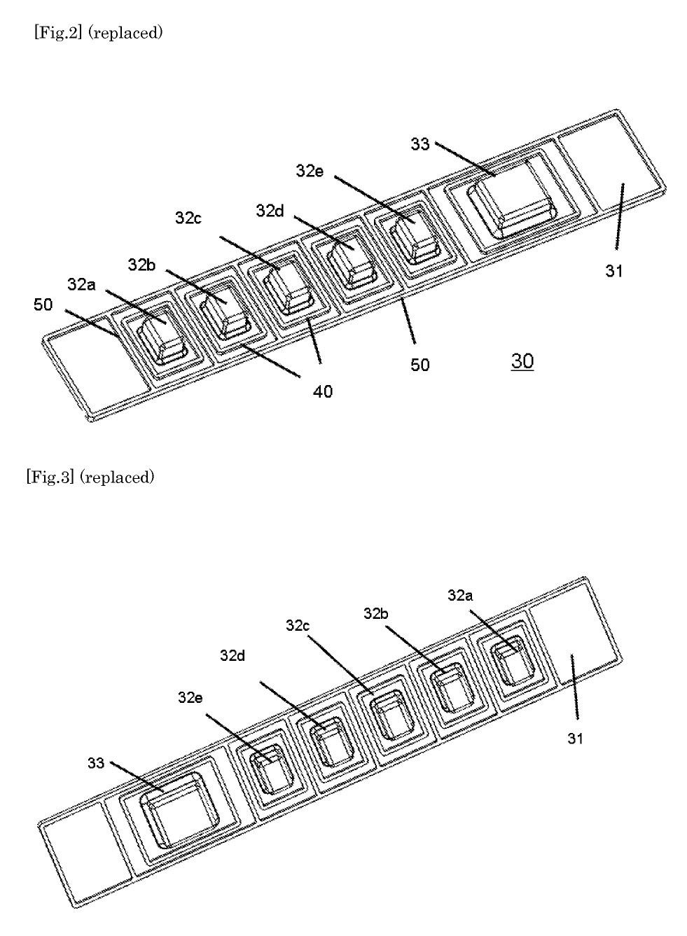

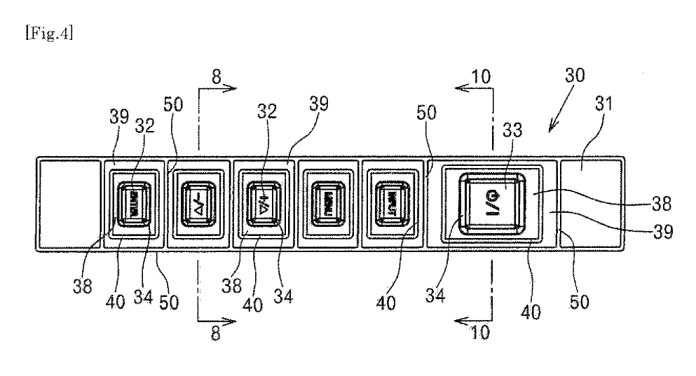

FIG. 2 and FIG. 3 are front perspective views of the button pad 30. FIG. 4 is a front view of the button pad 30. The button pad 30 has a plate-like button supporting plate 31, buttons 32a, 32b, 32c, 32d, 32e and 33 which are protruded from the plate 31. The button 32a is an “ENTER” button. The button 32b is a “DOWN” button for volume or channel. The button 32c is a “UP” button of for volume or channel. The button 32d is a “MENU” button. The button 32e is an “INPUT” button. The button 33 is an “ON/OFF” button of a power supply.

The button pad 30 is made by fabricating an elastic component such as rubber. In the button supporting plate 31, a plurality of first annular ribs 40 are formed so as to surround each of the buttons 32 and 33. In the outer circumference of the first ribs 40, second ribs 50 are formed. The second ribs 50 are provided so as to surround the outer edge of the button supporting plate 31 and to divide (or measure off) the neighboring first ribs 40.

The first rib 40 and the second rib 50 have height lower than the buttons 32 and 33. The first rib 40 and the second rib 50 are formed in the almost same height. Between the buttons and the first ribs 40, first grooves 38 are formed. Between the first ribs 40 and the second ribs 50, second grooves 39 are formed.

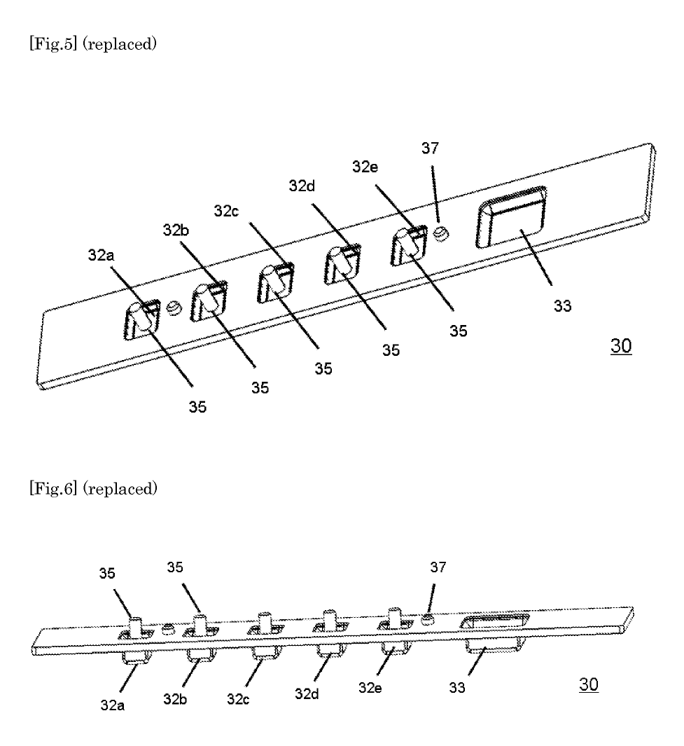

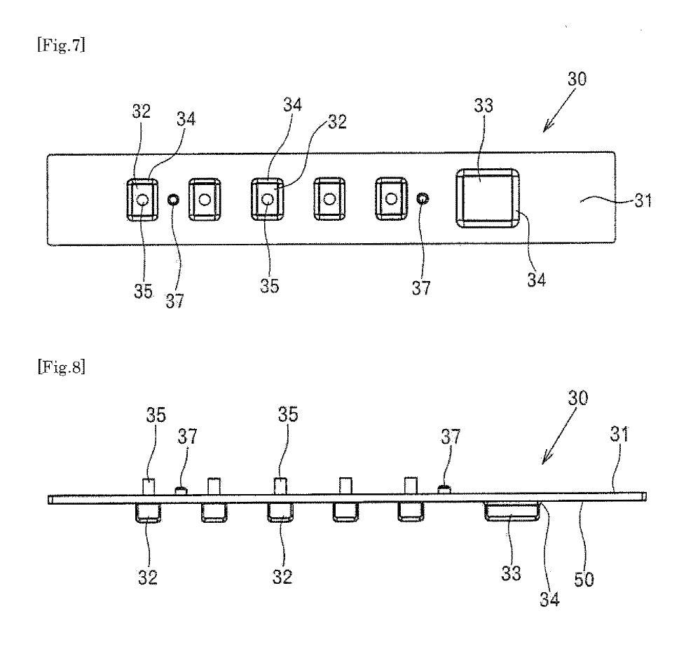

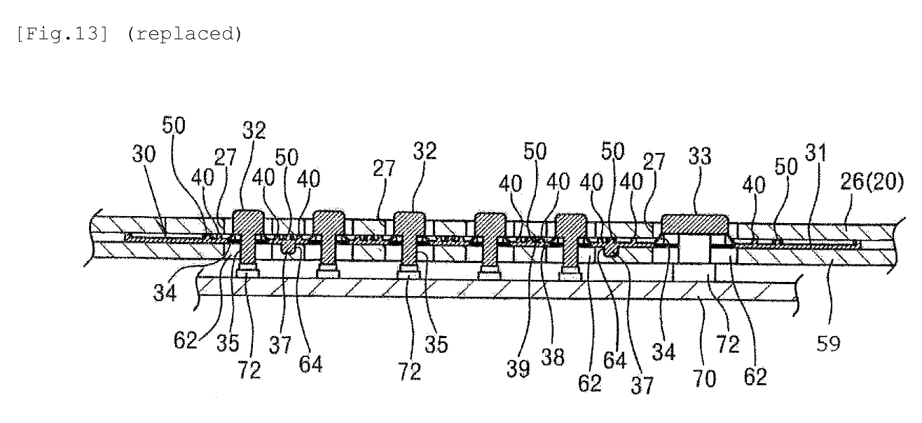

FIG. 4 is a back perspective view of the button pad 30. FIG. 5 is a side perspective view of the button pad 30. As shown in these figures, in the back side of the buttons 32, protrusions 35 for operating a button type switch 72 on a circuit board 70 (see FIG. 13) is formed. However, in the back side of the button 33, the protrusion 35 is not formed.

In the back side of the button pad 30, positioning protrusions 37 for positioning the button pad 30 is formed in two places. In order to prevent the button supporting plate 31 from being bent by the protrusion 37, the protrusion 37 is formed in the back side of the first rib 40 or the second rib 50.

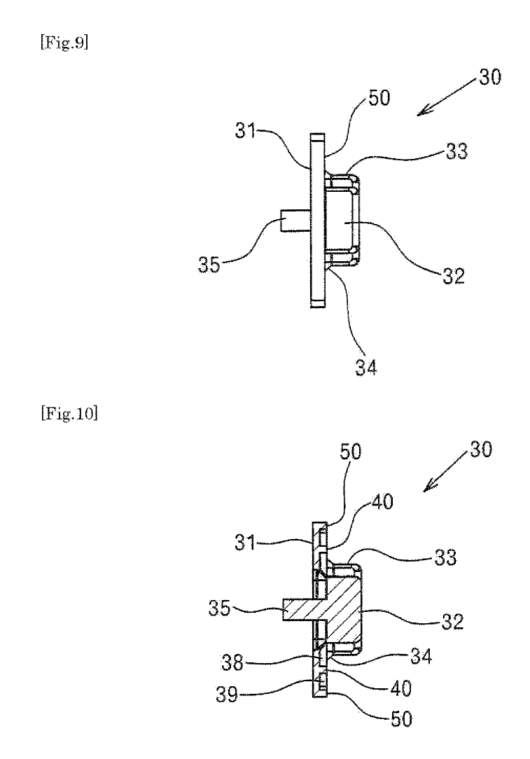

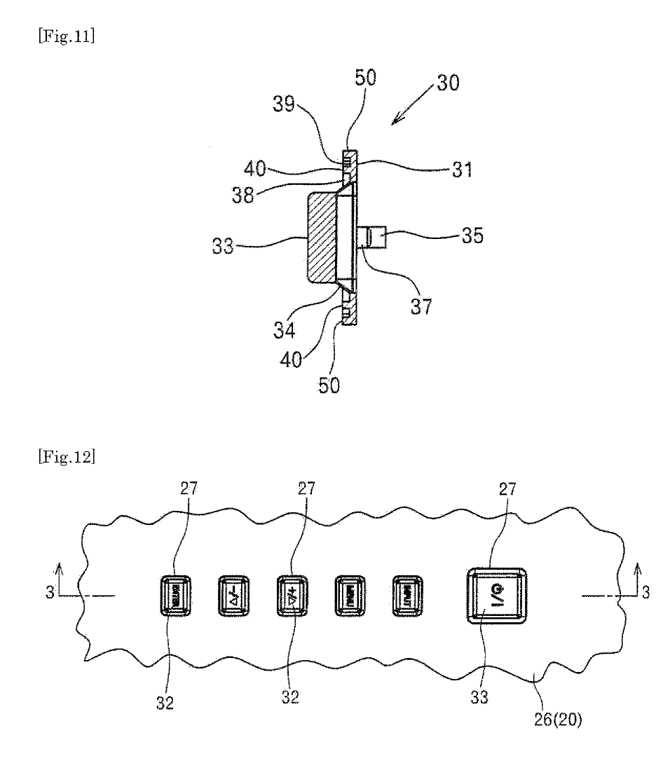

Referring to FIGS. 9 to 11, the button 32 and 33 are made thicker than the button supporting plate 31. The buttons 32 and 33 are connected by thin wall portions 34 which allow the movement of these buttons in the upper and lower direction.

FIG. 12 is a front view at the button pad 30 when the button pad 30 is equipped to the cabinet 20. FIG. 13 is a sectional view of the button pad 30 when the button pad 30 is equipped to the cabinet 20. The button pad 30 is arranged at the inner surface side of the rear panel 26, and each of the buttons 32 and 33 formed in the button pad 30 are protruded from the respective openings 27 formed in the rear panel 26.

The button pad 30 is arranged to the cabinet 20 by (1) adjusting the position of the buttons 32 and 33 to the openings 27, (2) contacting the first ribs 40 and the second ribs 50 to the inner side of the rear panel 26, and (3) sandwiching the buttons between the rear panel 26 and a board 59. Therefore, even when water is invaded from a space between the button 32 and the openings 27 (or a space between the button 33 and opening 27), water does not pass over the first rib 40, and stays in the first groove 38 formed between the buttons and the first rib 40.

However, when the button moves up and down by the user's operation, the button pad may be bent and water may invade inside from this bent portion. In order to prevent this, the waterproofing structure is augmented by surrounding the button by a double-ringed rib in the button pad 30.

In detail, when the button 32 (or 33) is pushed too hard, the first rib 40 may be bent and water may pass over the first rib 40. However, since second rib 50 is formed outside the first rib 40 and is provided so as to contact the rear panel 26, water does not invade inside the cabinet 20. The water which passed over the first rib 40 stays inside the second groove 39. The water inside the grooves 38 and 39 evaporate as time elapses.

In the board 59, a plurality of openings 62 are provided in the position corresponding to the buttons 32 and 33, so that the movement of these buttons are not disturbed when operated by a user. Further, in the board 59. a plurality of positioning holes 64 are provided so that the protrusion 37 formed in the button pad 30 can be fit into. The board 59 can be attached to the rear panel 26 by screwing it to the rear panel 26.

In the inner side surface of the board 59, a circuit board 70 having switches 72 which are pushed by each buttons 32 or 33 are arranged. These push-type switches 72 are arranged in the position facing the button 33 or protrusion 35 of the button 32.

Instead of above examples, other configuration may be adopted. For instance, the second rib 50 (1) surrounds the button supporting plate 31, and (2) separates the neighboring first ribs 40. However, the second rib 50 may be provided such that (1) it surrounds the button supporting plate 31, (2) but not separating the first ribs 40. Or, the second rib 50 may be a rib which surrounds each of the first ribs 40.

The above implementation may be applied to an electronic device other than the LCD display 10. The button pad 30 may be arranged in a place other than the rear panel 26.

In the above example, the button 32 and 33 are waterproofed by a plurality of ribs 40 and 50. Further, the display device 10 has an accommodation unit 100 which accommodates a connector for electronic cables. As shown in FIG. 1, the accommodation unit 100 is provided in the rear panel 26, below the buttons 32 and 33.

A removable cover 140 is attached by screws 150 to the accommodation unit 150. The connectors for connecting the cables are provided in the surface 101c or 101b. The surface 101c is the upper side inner wall of the accommodation unit 100. The surface 101b is a back wall of the accommodation unit 100.

The accommodation unit 100 is a casing which fits into an opening 29 provided in the rear panel 26, and has a peripheral wall 102 which is higher than rear panel 26. In the peripheral wall 102, a plurality of screw holes 104 for screwing the cover 140 by screw 150 are provided.

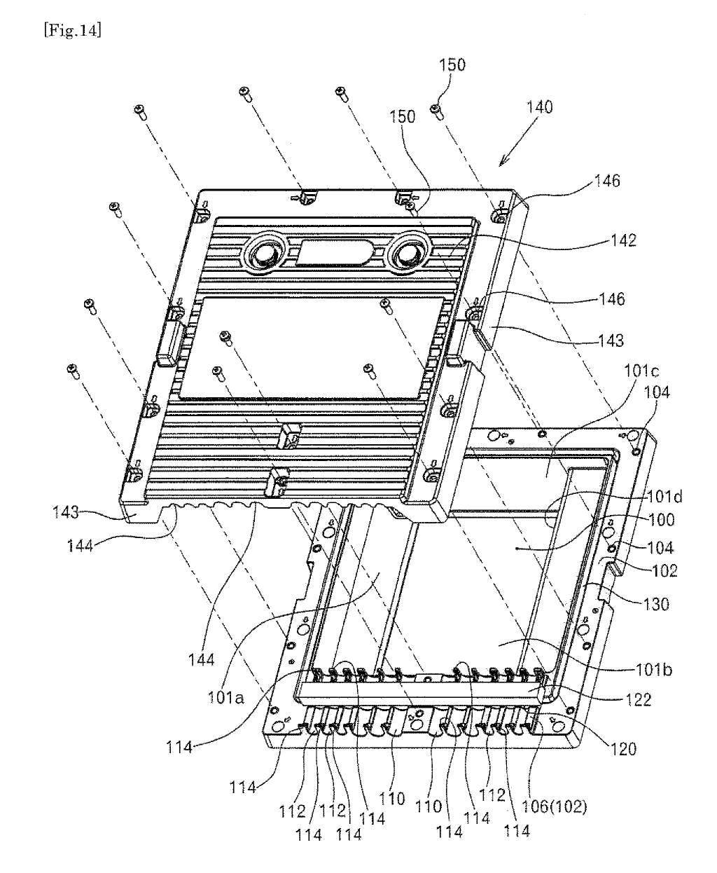

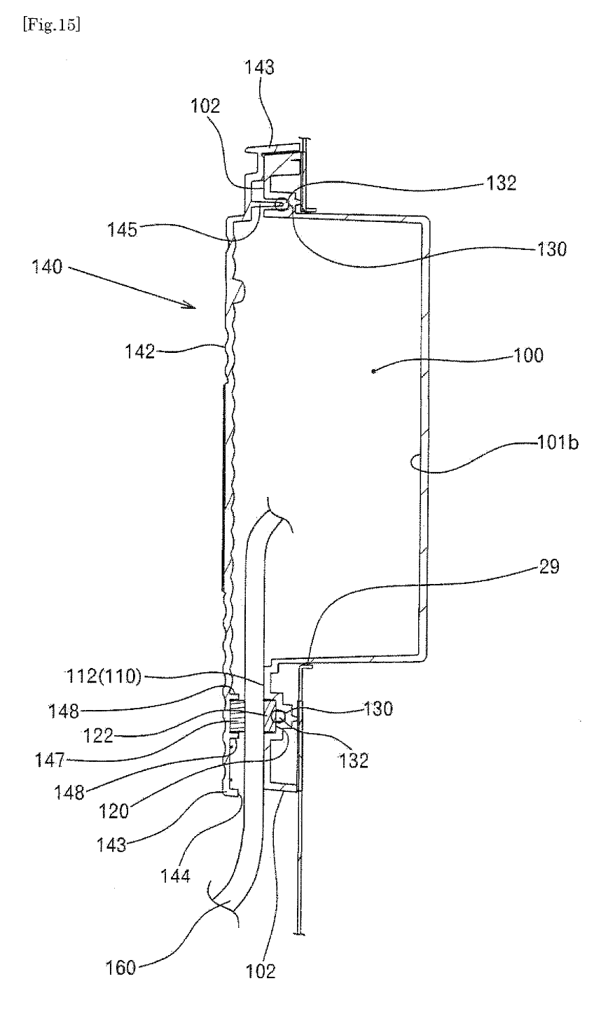

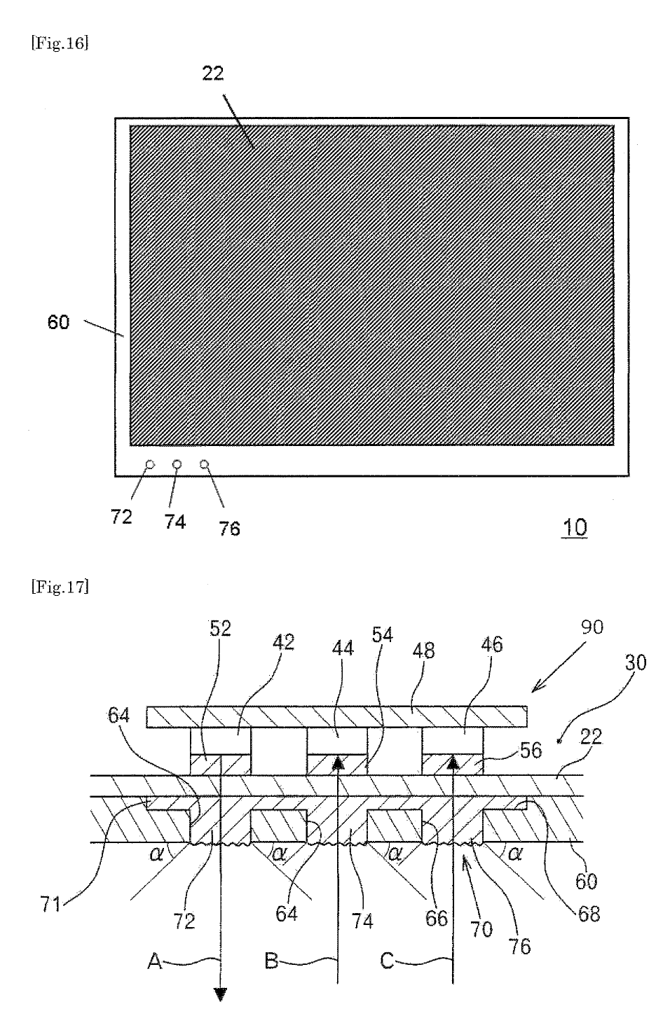

As shown in FIGS. 14 and 15, the peripheral wall 102 is a four-sided frame object. Among the four side of the wall, the one side is formed broader than the other three sides. In the broader side (cable passing surface 106), a plurality of first grooves 110 and 112 to which the electronic cables are inserted are formed. In this example, a vertically lower side is the cable passing surface 106. Along the surface 106, the grooves 110 and 112 are formed in the perpendicular direction.

The cross section of the first grooves 110 and 112 are semicircular shaped. The width of the grooves may vary depending on the width of the electronic cables 160 which are connected to the LCD display 100. For example, in FIG. 14, the first grooves 110 which are provided in the center portion are wider compared to the first grooves 112 in the outer portion.

In the both end of the first groove 110 and 112, a cable holding protrusions 114 are provided such that they prolong toward the cover 140. The protrusions 114 are formed like a rib. The heights of the protrusions 140 are designed such that the top side of the protrusion 114 is located slightly lower than the cover 140.

In the cable passing surface 106 of the peripheral wall 102, a second groove 120 which crosses the first grooves 110 and 112 is provided. To the second groove 120, a first sealing component 122, such as urethane, is fitted so that this first sealing component 122 protrudes from the groove 120. When the cover 140 is covered, the first sealing component 122 contacts the second sealing component 147 (which is mentioned later) provided on the cover 140. Thereby, it can prevent water or dust from invading inside the accommodation unit 100 from the first grooves 110 or 112.

Further, as shown in FIG. 14, in the peripheral wall 102, an annular third groove 130 is provided. The third groove 130 is formed deeper than the first grooves 110, 112 and the second groove 120. In the cable passing surface 106, the third groove 130 is provided so as to overlap the second groove 120. To the third groove 130, an annular third sealing component 132 is fitted.

To the third groove 130, a rib 145 (which is described later) which is protruded from the cover 140 is fitted. The tip of this rib 145 presses the third sealing component 132, and thereby it can prevent an invasion of the water or dust into the accommodation unit 100.

The accommodation unit 100 is covered by the cover 140. As shown in FIG. 14, the cover 140 has a top plate 142 covering the unit 100, and a horizontal wall 143 which protrudes toward the rear panel 26 from the top plate 142. In the top plate 142, a screw hole 146 for screwing the cover 140 to the peripheral wall 102 of the accommodation unit 30 is formed.

The horizontal wall 143 is provided such that it covers the outer side of the peripheral wall 102 of the accommodation unit 100. Among the wall 143, the portion which faces the first grooves 110 and 112 is concaved. In detail, concaves 144 which communicates the first grooves 110 (or 112) and the outside are formed. The concaves 144 are semicircular shaped, and by combining with semicircular first grooves 110 (or 112), circular openings for inserting electronic cables 160 are formed.

As shown in FIG. 15, in the inner side of the top plate 142, the second sealing component 147 is arranged in a position so as to contact the first sealing component 122, which is fitted to the second groove 120 of the peripheral wall 102. The second sealing component 147 may be formed by urethane etc., and is fitted between the walls 148 which protrude from the inner side surface of the top plate 142.

Further, at the top plate 142, a rib 145 which contacts a third sealing component 132 which is inserted in the third groove 130 is formed. In this example, since a portion of the third sealing component 132 in the third groove 130 overlaps the second sealing component 147, the rib 145 is protruded along the second sealing component 147.

By screwing the cover 140 by screw 150, the first groove 110 (or 112) and the concave 144 forms a circular opening, and by contacting the first sealing component 122 and the second sealing component 147, a closed space is formed between the top plate 72 and the first groove 110 (or 112). Further, by fitting the rib 145 into the third groove 130, the tip of the rib 145 contacts the third sealing component 132. Thereby, the accommodation unit 100 can be prevented from an invasion of water or dust.

Electronic cables 160 such as a power cord, an antenna code, or an external apparatuses connecting cord can be connected in a state where the cover 140 is removed from the accommodation unit 100. The electronic cable 160 is connected to connector terminal provided in the surface 101b. The connected electronic cables 160 are drawn outside via first grooves 110 or 112. Here, it is necessary to bend these cables 160 in order to lead the cables 160 to these grooves. The cables 160 may be twisted at that time. The bent electronic cables 160 may repel due to its flexibility, and thus it is difficult to lead electronic cables 160 to the first grooves 110 or 112. However, according to the above example, since the protrusions 114 are formed in the both ends of the first grooves 110 (or 112) and the grooves can be formed deeper, it becomes easier to guide the electronic cables 160 to the first grooves 110 or 112. Thus, it can prevent the electronic cables 160 from falling out from the grooves 110 (or 112).

In the above structure, the electronic cables 160 can be fitted stably in the first grooves 110 or 112. Thus, it is not necessary to hold electronic cables 160 when the screwing the cover 140 by screw 150. Thus, it becomes easy to attach the cover 140.

By screwing the cover 140 by screw 150, as shown in FIG. 15, the electronic cables 160 is drawn outside via an opening formed by the first groove 110 and a concave 144 (or by the groove 112 and a concave 144). Simultaneously, the electronic cables 160 are inserted between the first sealing component 122 and the second sealing component 147 without a gap. Therefore, neither water nor dust invades into the accommodation unit 10. Further, since the electronic cables 160 drawn from the accommodation unit 100 is sandwiched by the first seal component 122 and the second sealing component 147, the electronic cables 160 is not unplugged from the connector terminal even when this electronic cables 160 is pulled by some power.

In the portion where the electronic cables 160 are not inserted, the first sealing component 122 and the second sealing component 147 are contacted each other directly. In the other three sides, the rib 145 of the cover 140 fits into the third grooves 130 and contacts the third sealing component 132, and thus, an invasion of the water or dust into the accommodation unit 100 is prevented.

As described above, by applying the different waterproofing structure for the buttons 32 (or 33), and the accommodation unit 100 accommodating the connector terminal for electronic cables, the waterproofing performance of the electronic device is improved.

That is, in the LCD display 10, while the waterproofing of the connector terminal for electronic cables 160 is realized by a rigid structure, the waterproofing of the buttons is realized by a simple first structure.

### (2. Waterproofing Structure of the Photo Detecting Unit)

It is desired by some users to operate an outdoor-use display device using a remote controller as they do in the indoor-use displays. However, the photo sensor for detecting signals from the remote controller is usually provided in the casing of the display device. Thus it was necessary to waterproof the photo sensor.

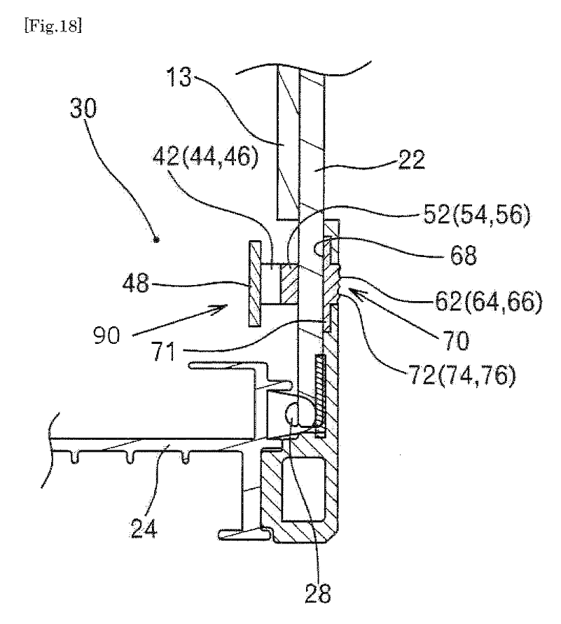

FIG. 16 is a front view of the LCD display device 10. The front side of the LCD unit 12 is covered by a glass panel 22 which functions as a transparent protection component for the LCD panel. The glass panel 22 is supported by a frame 60. In the front lower left side of the frame 60, lenses 72, 74, and 76 are inserted as shown in FIG. 17. Inside these lenses, a light emitting element (LED 42), a light detecting unit 44 which detects infrared rays, and an illumination sensor 46 which detects brightness are provided. Instead of the glass panel 22, a plastic or an acrylic panel can also be utilized.

The glass panel 22 and the side casing 24 are connected by a gasket 28. Simultaneously, the side casing 24 and the rear panel 26 are connected by the gasket 28. Thereby, a waterproofing structure 30 is formed inside the cabinet 20. In the side casing 24, ribs 29 for holding the gasket 28 are provided.

The display panel 13 and the glass panel 22 are integrated by a bonding technology.

LED 42 displays a power supplying state of the LCD display 10. The light receiving device 44 receives infrared rays from a remote control unit for operation of the LCD display 10. The illumination sensor 46 is for detecting the brightness of the surroundings and adjusting the luminosity of a display panel 13.

Each of the devices 42, 44, and 46 are arranged on a circuit board 48 and configures a device unit 90. The device unit 90 is connected to a LCD unit 12 and an electronic component unit 14 via a flexible substrate.

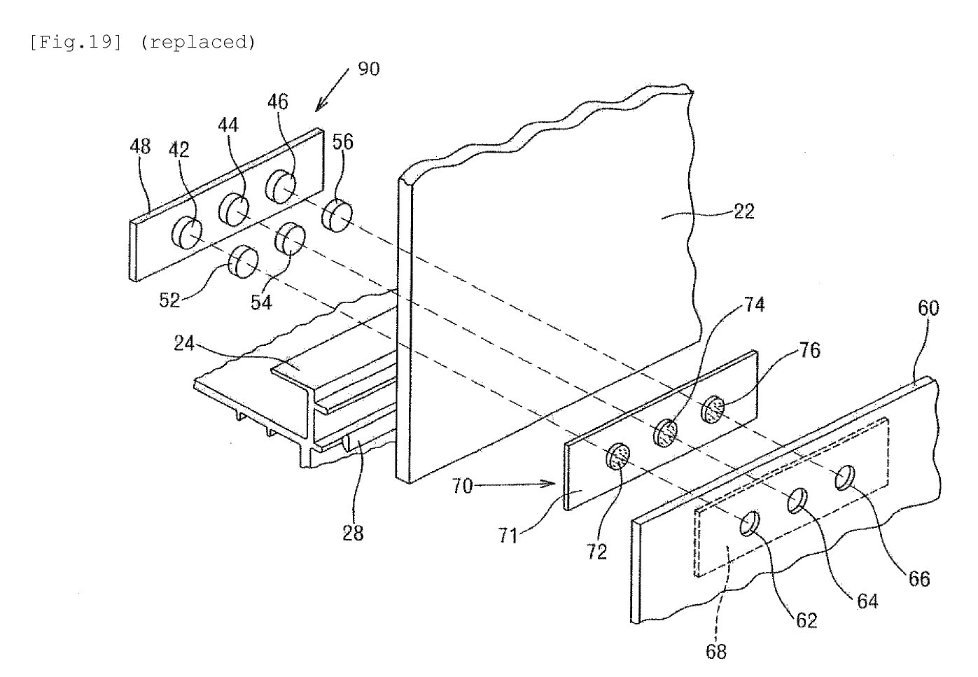

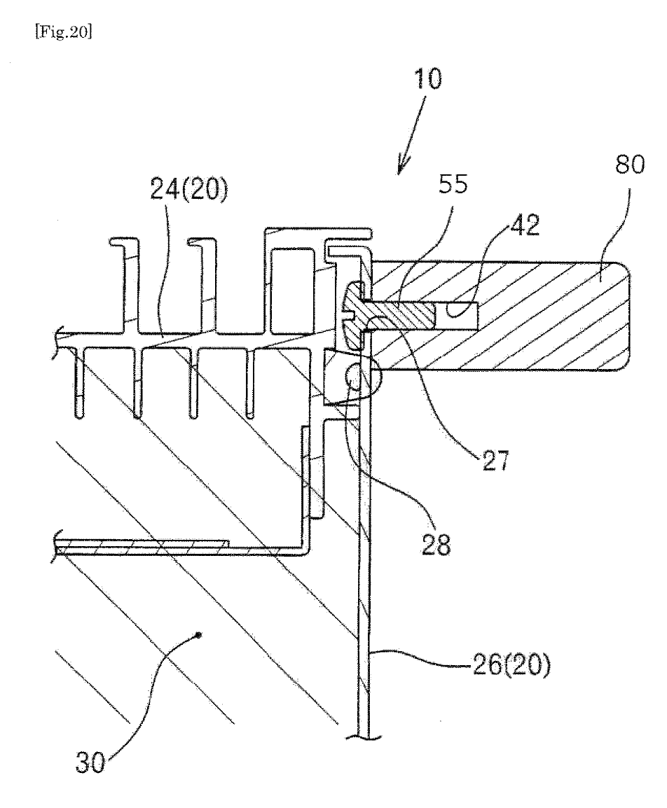

As shown in FIGS. 17 and 19, the device unit 90 is arranged inside the gasket 28, and is arranged so that each of the devices 42, 44, and 46 faces the glass panel 22. Thereby, it is not necessary to prepare a special structure to waterproof the device unit 90. Further, electronic cables can be connected between the device unit 90 and the LCD unit 12 (or the electronic component unit 14) inside the waterproofing structure 30. Further, since the glass panel 22 can transmit the light, the performance of the devices 42, 44, and 46 are not deteriorated even though they are arranged inside the waterproofing structure 30.

In detail, as shown in FIGS. 17, 18 and 19, the devices 42, 44 and 46 are arranged facing glass plate 22 with lens 52, 54 or 56 in between. The lens 52 which is arranged in front of LED 42 converge the light emitted from the LED 42. The light which passed the lens 52 is emitted outside via the glass panel 22. The lens 54 and 56 converge the light which enters from the glass panel 22. The light converged by these lens eventually reaches the devices 44 or 46.

The frame 60 is consisted by an opaque resin, and as shown in FIG. 18, the frame 60 is prolonged to a position higher (in the vertical direction) than the devices 42, 44, and 46 in the front of the glass panel 22.

As shown in FIGS. 17 to 19, in the frame 60, the openings 62, 64 and 66 for accepting the passage of the light are provided in the position facing the devices 42, 44 and 46 respectively. In the rear side of the frame 60, a concave 68 is formed in the surroundings of these openings. To this concave, a base 71 of the lens unit 70, in which its back side contacts the glass panel 22, is fitted.

In the lens unit 70, a plurality of lenses 72, 74 and 76, each of which fits into the openings 62, 64 and 66 respectively, are provided on the base 71. Each of the lenses is fabricated so that the side facing outside from the openings becomes a rough side. By this, the light coming from outside can be received by wide angle. Simultaneously, the light emitted from the LED 42 can be emitted from the display device 10 by wide angle. Here, the angle is shown by letter alpha in FIG. 17. When each of the lenses 72, 74 and 76 is made by rough sides, the angle alpha in FIG. 17 is approximately 45 degrees.

In the LCD display 10, as shown in an arrow A in the FIG. 17, the light emitted from the LED 42 is converged by the lens 52, then passes through the glass panel 22 and the lens 62, and diffuses on the surface of the lens 62. Then, this light is emitted outside.

As shown in an arrow B in the FIG. 17, an infrared ray from the remote controller passes the lens 64, the glass panel 22, and the lens 54. Then, the light converged by these lenses reaches the light receiving unit 44. By making lens 64 a rough surface, an infrared ray from various directions can reach the unit 44.

As shown in an arrow C in the FIG. 17, the external light (such as sunlight) passes the lens 66, the glass panel 22 and the lens 56. Then, the light converged by these lenses reaches the illumination sensor 46. By making the lens 66 a rough surface, the external light from various directions can reach the sensor 46.

According to the above example, by arranging the devices 42, 44 and 46 inside the waterproofing structure 30, it is unnecessary to prepare a dedicated waterproofing structure for these devices. Thus, there is an advantage that it can suppress an increase in the number of components and cost.

### (3. Waterproofing Structure of a Grip Part)

The outdoor-use display devices tend to become larger than the indoor-use displays. Especially, when a metal cabinet is employed, its weight becomes very large. Thus, it is desired to prepare a grip in the cabinet so that it is easy for user to carry the display device. However, when a screw hole for attaching this grip is provided on the cabinet, water may invade inside from this portion. Hereafter, a waterproofing structure for this grip portion is explained.

Referring to FIG. 1 again, in the LCD display 10, a plurality of screw holes 25 are provided outside the gasket 28 in the back side of the side casing 24.

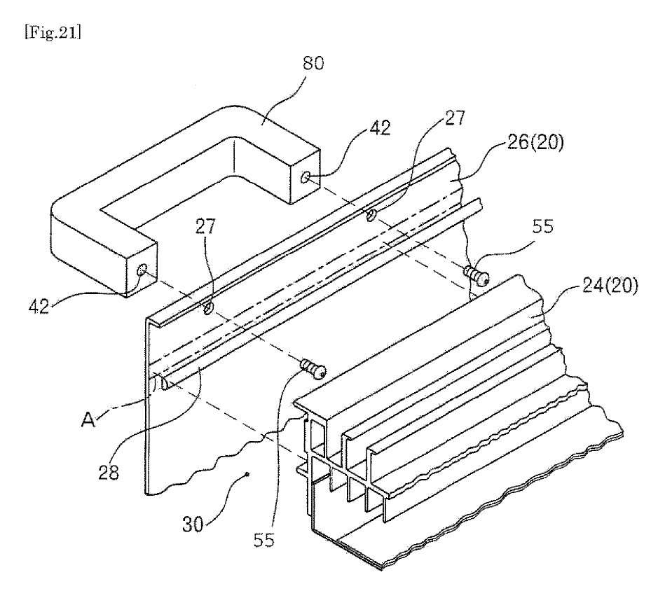

As shown in FIGS. 20 and 21, the rear panel 26 is extended outside the gasket 28 which is the boundary of the waterproofing structure 30. In the edge side of the extended portion, a plurality of the grips 40 is provided as shown in FIG. 1. In FIG. 21, the boundary of the waterproofing structure 30, in which the rear panel 26 and the gasket 28 contacts, is shown by a dashed line A.

In the outside of the gasket 28, screw holes 27 for attaching the grip 80 and screw holes 27a for attaching the rear panel 26 to the side casing 24 is provided near the edge portion of the rear panel 26.

To the screw holes 27, the grip 80 for carrying is screwed by screw 50. As shown in the figure, in the grip 80, a pair of screw holes 42 for screwing by screw 50 is provided in its left side and right side.

Thereby, as shown in FIGS. 20 and 21, the grip 80 can be attached to the rear panel 26 by screwing a screw 50 outside the waterproofing structure 30. In this example, the grip 80 should be screwed by screw 50 before forming the waterproofing structure 30 because the side casing 24 hides the head of the screw 50 if the waterproofing structure 30 is already formed.

After the grip 80 is screwed by screw 50, the gasket 28 is sandwiched between the side casing 24 and the rear panel 26. Then, the screw holes 25 of the side casing 24 and the screw holes 27a of the rear panel 26 are aligned and screwed. Thereby, the rear panel 26 is connected with the side casing 24.

According to the above example, the screw holes 27 for attaching the grip 80 to the rear panel 26 and the screw holes 27a for attaching the rear panel 26 to the side casing 24 are provided outside the waterproofing structure 30. Thus, the waterproofing structure 30 is not deteriorated by the attachment of the grip 80. As a result, it is not necessary to prepare waterproofing gaskets for each of the screws 50 for attaching the grip 80 (typically the price of these gaskets are about several hundred Japanese yen, which is about a couple dollars for each), and thus it can reduce the number of the components or cost.

Further, the grip 80, to which the weight of the LCD display is applied, is attached outside of the waterproofing structure 30. Thereby, even when the screw is loosened because of the weight of the LCD display, the waterproofing performance is not deteriorated.

The attaching position for the grip 80 is not limited to the rear panel 26. The grip 80 may be attached to the side casing 24, as far as it is attached outside the waterproofing structure 30.

The present invention may be applied not only to above described LCD displays, but also to the plasma panel display or other electronic devices.

What is claimed is:

1. A button pad made by an elastic component, comprising:
a protruding portion provided in a position corresponding to one or more buttons, and
a plurality of annular ribs provided in the periphery of the single button.

2. An electronic device, comprising:
a cabinet;
a button provided on the cabinet;
a switch being pushed by the button;
a circuit board including the switch, and
a button pad which comprises:
(a) a button portion;
(b) a peripheral portion which is in the surroundings of the button portion, and
(c) a plurality of annular ribs provided on the button pad in a position corresponding to the periphery of the button, wherein, each of the rib is arranged so as to contact the inner surface of the cabinet.

3. An outdoor use display device, comprising:
a cabinet;
a button provided in the cabinet;
a first structure for waterproofing the button, and
a second structure for waterproofing a connecting portion with an external electronic cables, wherein
the first structure comprises:
(i) a button pad which covers the button, and
(ii) a plurality of annular ribs which are provided on the button pad and in a position corresponding to the peripheral of the button;
the second structure comprises:
(i) an accommodation unit provided on the cabinet so as to form a concaved portion, wherein the connecting portion is provided on the rear wall or the bottom wall of the accommodation unit, and
(ii) a cover component which covers the accommodation unit.

4. A display device, comprising:
a display panel which displays an image;
a transparent protection component which covers the front side of the display panel;
a cabinet which covers at least the lateral side and the back side of the display panel, and
a light detector which receives an operating signal from a remote controller, wherein the light detector is arranged inside the cabinet, at the inner side of the transparent protection component and the outer peripheral of the display panel.

5. The display device of claim 4, further comprising:
a frame which holds the transparent protection component;
an opening provided in the frame, and
a lens inserted in the opening for leading the light from the remote controller to the light receiving unit.

6. An electronic device, comprising:
a cabinet;
an electronic component which is accommodated inside the cabinet;
a waterproofing structure for protecting the electronic components from a water intrusion;
a screw hole provided on the cabinet, in a position corresponding to the outer side of the waterproofing structure, and
a grip for carrying the electronic device, the grip being screwed to the screw hole.
